(19) United States
(12) Patent Application Publication
(10) Pub. No.: US 2025/0101571 A1
(43) Pub. Date: Mar. 27, 2025

(54) EVAPORATION PUMP

(71) Applicant: Tokamak Energy Ltd, Abingdon, Oxfordshire (GB)

(72) Inventors: Juan Benayas, Abingdon (GB); Vivian Lee, Abingdon (GB); Robert Bamber, Abingdon (GB); Patrick Bunting, Abingdon (GB); Ghassan Antar, Abingdon (GB); Simon Hanks, Abingdon (GB); Konstantin Moshkunov, Abingdon (GB)

(21) Appl. No.: 18/728,477

(22) PCT Filed: Jan. 16, 2023
(86) PCT No.: PCT/EP2023/050909

§ 371 Date: Jul. 12, 2024

(30) Foreign Application Priority Data
Jan. 14, 2022 (GB) 2200451.9

(51) Int. Cl. C23C 14/24; B01J 20/04; B01J 20/32; C23C 14/14; F04B 37/02; H05H 1/12

(52) U.S. Cl. CPC C23C 14/24; B01J 20/04; B01J 20/3214; B01J 20/3236; C23C 14/14; F04B 37/02; H05H 1/12

(57) ABSTRACT

A method of operating an evaporation pump system in a chamber at partial vacuum is provided. The method includes heating a getter source to form a getter vapour; depositing the getter vapour onto a first target surface arranged within the chamber to form a getter layer; and providing a replenished target surface within the chamber, and onto which the getter vapour can be deposited, by at least partially removing, from the first target surface, the getter layer and any chemisorbed, and/or physisorbed products present within the getter layer, said step being carried out within the chamber; and/or arranging a second target surface within the chamber, wherein, the getter source comprises lithium.

### TECHNICAL FIELD

The invention relates to an evaporation pump system, and a method of operating an evaporation pump system.

### BACKGROUND

A vacuum pump is a device that extracts gas from an enclosed volume to form, or maintain, a partial vacuum. A getter pump is a type of vacuum pump. Broadly, there are two main types of getter pump: the non-evaporable getter (NEG) and the evaporable getter (EG).

In getter pumps, a getter material is used to extract molecules or atoms from the enclosed volume by physisorption, chemisorption and/or absorption. In physisorption, molecules or atoms that collide with the getter surface temporarily adhere (or “stick”) to the getter surface. Physisorption is reversible, meaning that the molecules or atoms may be released without achieving a pumping effect. However, in chemisorption, molecules or atoms chemically bond with the getter, thus requiring considerably larger temperatures to release back them back into the volume. This process is irreversible without heating and hence generates a pumping effect.

In NEG pumps, the getter is typically an alloy or sintered powder mixture comprising, for example, Al, Zr, Ti, V and Fe. These getter materials are expensive and technically challenging to produce (e.g., processing of reactive powders is inherently dangerous). Molecules such as oxygen, nitrogen, carbon dioxide and water vapour form various oxides, nitrides and carbides via chemisorption with the getter, whereas hydrogen and other molecules (e.g., hydrocarbons) dissociate at the getter surface and diffuse into the getter bulk in solid solution. Over time, the getter surface saturates with chemisorption products, which slows the pumping effect and, to an extent, absorption. For this reason, NEG pumps can be “reactivated” by heating the getter to temperatures around 700K. This encourages the chemisorption products, which do not decompose at these temperatures, to diffuse away from the surface into the getter bulk. Other chemisorbed products (e.g., any chemisorbed hydrogen present) decompose and are released back into vacuum.

At the same time, the getter bulk in NEG pumps may saturate with absorbed products (e.g. dissociated hydrogen), which limits further absorption. As absorption is reversible, getters in NEG pumps can be “regenerated” by heating to release these absorbed products back into vacuum.

In EG pumps, a filament consisting of a titanium-molybdenum alloy is heated by passing a current through it to temperatures in excess of 1600K. At around 1600K, the titanium sublimates and is deposited onto a surface by physical vapour deposition (PVD) to form the getter. Similar to NEG pumps, oxygen, carbon dioxide and nitrogen are chemisorbed to the surface of the getter, whereas hydrogen diffuses into the bulk. The filament is generally heated continuously to deposit a new layer. Alternatively, the filament may be reheated only after the deposited titanium layer saturates. Eventually, the filament needs replacement. Other evaporable getters, which comprise Ba, Ca or Ti, are also known.

The bulk of a getter material generally refers to the volume of the getter material away from the surface.

### SUMMARY

It is an object of the present invention to provide a new and useful evaporation pump system, for example a high vacuum (HV, 10⁻⁷ to 10⁻³ mbar), or ultra-high vacuum (UHV; 10⁻¹² to 10⁻⁷ mbar) evaporation pump system.

The invention provides an evaporation pump system and a method of operating an evaporation pump system in accordance with the accompanying claims.

The evaporation pump system according to the present invention may have one or more of the following advantages:
it is efficient at absorbing hydrogen and other gaseous particles, such as oxygen, nitrogen, carbon dioxide and water vapour;
it is compact and lightweight;
it requires low maintenance and is absent of vibration (no moving parts);
operation temperatures are low (compared to EG pumps) (<1100K); and
it is relatively easy and cheap to manufacture.

### BRIEF DESCRIPTION OF THE DRAWINGS

Embodiments of the invention will now be described for the sake of example only with reference to the accompanying drawings, in which:

FIGS. 1, 2 and 3 are side-profile schematic views of evaporation pump systems;

FIG. 4 is a method diagram;

FIG. 5 is a schematic illustration of a target surface insertion and removal mechanism; and

FIG. 6 is a schematic view of a pump assembly.

### DETAILED DESCRIPTION

Existing Getter Pumps have the Following Problems:
Conventional non-evaporable and evaporable getter materials are expensive and difficult to fabricate because they are comprised from multiple constituents with different melting points.
Although existing getter materials are effective at removing hydrogen to the getter bulk, other gases, such as oxygen, form compounds by chemisorption that remain at the getter surface. A corollary is that:
   in NEG pumps, the getter surface saturates relatively quickly and “reactivation” to remove the saturated layer is time consuming; and
   in EG pumps, a high volumetric efficiency requires fine control and/or optimisation of the chemisorption and deposition rates, which may be difficult in practice.

The evaporator pump system described herein at least partially solves some of these problems.

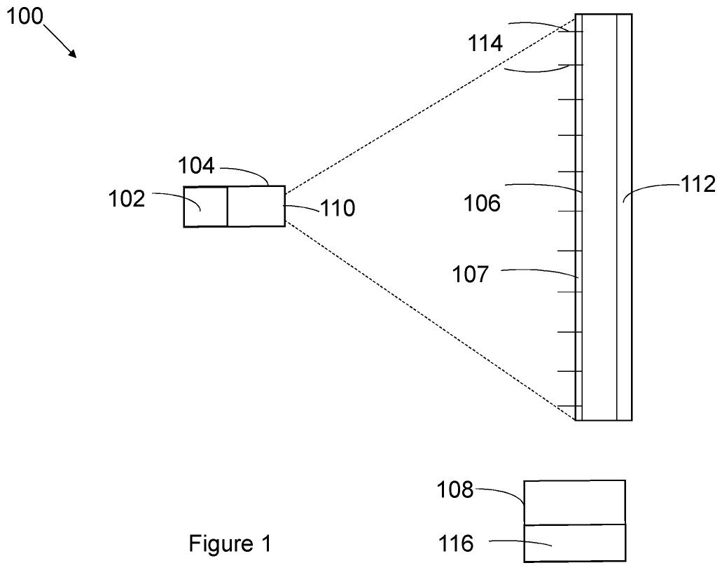

FIG. 1 shows a side-profile schematic view of an evaporator pump system 100. The evaporator pump system 100 comprises an evaporator 104; a target surface 106, such as a plate or disc; and a collector 108. The evaporator pump system 100 may, for example, be operated in a chamber in a HV or UHV environment and in particular, used to achieve or maintain a UHV, optionally with a specific gas load. A chamber is any enclosed volume in which pumping of a particular gaseous species is desired, and in which the pump system is placed. In a specific example, the chamber is the magnetic-confinement chamber of a tokamak.

The evaporator 104 provides a housing for a getter source 102. The getter source 102 is initially solid. The housing (e.g., a crucible) comprises an opening 110 at one end. Optionally, the evaporator 104 contains one or more heating elements, such as a filament of wire, in contact with, or close to, the getter source 102. A current may be passed through the filament of wire to heat the getter source 102. Alternatively, the getter source 102 is heated remotely, for example, by radio-frequency heating. The heating elements are configured to generate sufficient heating to melt and, at least partially, evaporate the getter source 102 to form getter vapour. Other heating methods suitable for forming getter vapour are possible, as appreciated by the skilled reader.

The evaporation rate of the getter source 102 increases monotonically with temperature, but at temperatures greater than a critical temperature (T_{c1}), the housing and getter source may chemically react and/or the housing may break. Preferably, although not necessarily, the temperature of the evaporator 104 remains below this critical temperature. The critical temperature is dependent on the material of the getter source 102 and the housing. One or more thermocouples may therefore be used to provide feedback to a temperature controller to regulate the temperature of the evaporator 104 and the getter source 102 and their heating rates.

The temperature of the getter source 102 is set to adjust the rate of evaporation of the getter source 102. The quantity of getter vapour is controlled based on the gas pressure and/or temperature of the environment (e.g., the number of moles of gas present). This reduces consumption of the getter source 102, which reduces maintenance (e.g., replacement, or (lithium) feeding, of the getter source 102) and cost.

The getter vapour then exits the evaporator housing through the opening 110 and condenses onto the target surface 106, which is arranged to oppose the opening 110 in the evaporator housing. The layer or film, which forms on the target surface 106, is known as the getter layer 107. The getter layer 107 refers to the deposited getter vapour absent any impurities that form during pumping. During operation, the getter layer pumps or captures impurities (e.g., atoms or molecules) from the partial vacuum environment in which the target surface 106 is disposed. These impurities, when captured by the getter layer 107, may be referred to herein as the “getter products” because they are formed by the gettering effect of the getter layer 107. As these getter products form, the getter layer 107 is used up. The getter layer 107 may be either solid or liquid. As the pumping effect of the getter layer 107 increases with increasing surface area of the getter layer 107, it is preferable (although not essential) to maximise the surface area of the getter layer 107 deposited on the target surface 106.

To an extent, the opening 110 in the evaporator housing directs the getter vapour towards the target surface 106. Under HV or UHV conditions, the mean free path of the getter vapour is relatively large (>50 mm) and hence the getter vapour exiting the opening 110 of the evaporator 104, to a first approximation, may trace a straight line (two such paths are denoted in FIG. 1 by the dotted line). The housing can therefore be oriented/angled relative to the target surface 106 to ensure that the getter vapour deposits on the target surface, as opposed to other surfaces.

The lateral spacing between the target surface 106 and the opening 110 in the evaporator housing may also be varied to optimise the total surface area of the getter layer 107 that deposits onto the target surface 106. More specifically, the lateral spacing may be varied, such that the diameter of the “cone”, traced by the getter vapour as it diverges from the opening 110 to the target surface 106, substantially matches the size (e.g., diameter) of the target surface 106. In a specific example, the target surface 106 has a diameter of 30 cm and the separation between the opening 110 and target surface 106 is 10 cm. In general, the distance between the opening 110 of the evaporator and the target surface 106 may be a third of the diameter of the target surface 106.

Optionally, the target surface 106 comprises an array of protrusions 114 (for example, pins) that extend away from the target surface 106. The array of protrusions 114 are preferably integral to the target surface 106. For example, they may be machined into a disc or plate shaped blank. The array of protrusions 114 could however be machined and attached to the target surface 106 separately, as the skilled reader appreciates. Alternatively, the array of “protrusions” 114 may be an array of holes machined into the target surface 106. The array of protrusions 114 increase the surface area of the target surface 106 without increasing its size (e.g., diameter), which improves the volumetric pumping strength. To an extent, the array of protrusions 114 also improve the rate of condensation of the getter vapour onto the target surface 106, although this is primarily controlled by the undercooling of the target surface 106. In a specific example, the spacing in the array of protrusions is around 5 mm.

In FIG. 1, the target surface 106 comprises one or more heating elements 112. The heating elements 112 may either be attached to, or form an integral part of, the target surface 106. The one or more heating elements 112 may be releasably attached to the target surface 106 so that each or all of the heating elements 112 can be removed from the target surface 106. In an example, the heating elements 112 form a “hot” plate disposed on the “back” side of the target surface 106, beneath the deposited getter layer 107. Alternatively, the target surface 106 is heated remotely by radio-frequency heating (not shown). Preferably, the temperature of the target surface 106 is kept below a critical temperature (T_{c2}) to avoid excessive evaporation of the getter layer 107 back into the vacuum. The value of the critical temperature (T_{c2}) with a getter source comprising lithium is around 470K.

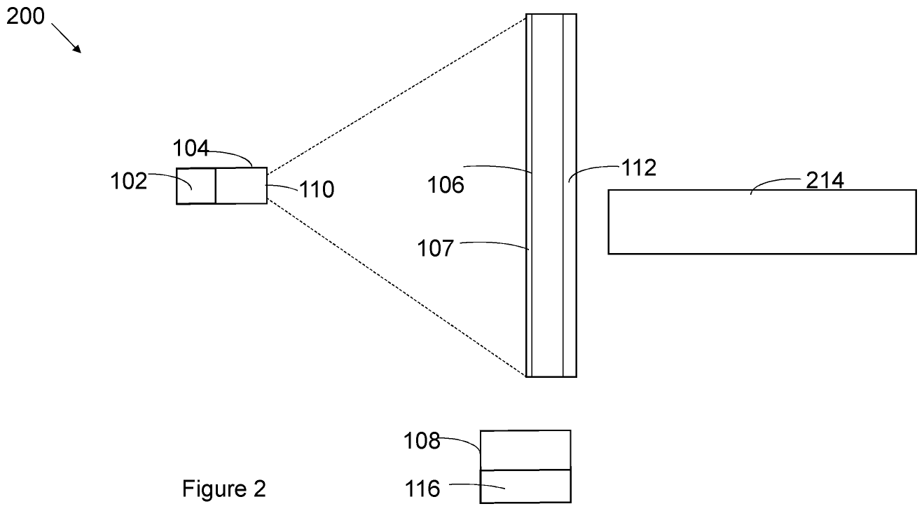

FIG. 2 shows a side-profile schematic view of an alternative evaporator pump system 200. The evaporator pump system 200 differs from the evaporator pump system 100 of FIG. 1 in that it additionally comprises a cooling element 214 which is operable to be placed in thermal contact with the target surface 106. The target surface 106 is also shown not to include an array of protrusions, although the presence of such a feature is possible. The cooling element is shown as being elongate or finger-like, but other shapes are possible. The cooling element is coupled to a drive mechanism (not shown) so that the cooling element 214 can be positioned into, and out from, thermal contact with the target surface 106. Known drive mechanisms to achieve this function are known to the skilled reader.

In FIG. 2, the cooling element 214 is shown in a retracted position (i.e., not in thermal contact with the target surface). However, the cooling element 214 is operable to be moved into an extended position (i.e., in thermal contact with the target surface) using the drive mechanism. In the extended position, the cooling element extracts thermal energy from the target surface 106 via thermal conduction, provided its temperature is lower than that of the target surface. Cooling rates for the target surface 106 (e.g., following its heating) are therefore higher compared with the evaporation pump system 100 of FIG. 1.

The target surface 106 of the pump system in FIG. 2 can therefore be held at lower temperatures (i.e., temperatures lower than 450K) more easily than the pump system of FIG. 1. At such temperatures (i.e., lower than 450K), evaporated lithium would (as the getter material) solidify when in contact with the target surface 106. The lithium-containing getter layer 107 which forms acts as a pump and trap gases within the getter layer 107. In order to subsequently collect the getter layer 107 and the getter products from the target surface 106, the getter layer 107 is melted (i.e., heated above its melting point) using heating elements 112 so that it 107, and some of the getter products contained therein, flow into collector 108 Prior to, or during this heating step, cooling element 214 is detached (i.e., retracted) from the target surface 106. After the getter layer 107 and some of the getter products contained therein are transferred to the collector 108, the cooling element 214 can be reattached (i.e., extended into thermal contact) to the target surface 106.

Metals have a tendency of releasing gas (and in particular hydrogen) at elevated temperatures when in partial vacuum. The rate of release of which increases monotonically with temperature and scales linearly with the surface area of the hot element exposed to vacuum. This release of gas is detrimental to the pumping effect of the system. Heating elements, such as filamentary wires, can also release gas when used to heat the target surface 106. Therefore, the pumping performance of systems 100, 200 can be improved by minimising the temperature, and total surface area of heating elements 112. Direct Ohmic heating or radio-frequency heating of the evaporator 104 is beneficial in this regard since additional heating elements are not needed for the indirect heating of the evaporator 104. Cooling systems can be used to reduce the temperature of other hot elements in the system 200. For example, cooling element 214 forms part of a cooling system (not shown) which removes thermal energy from the target surface 106 in which it is in thermal contact with. Cooling systems for that purpose, for example water cooling systems, are known to the skilled reader.

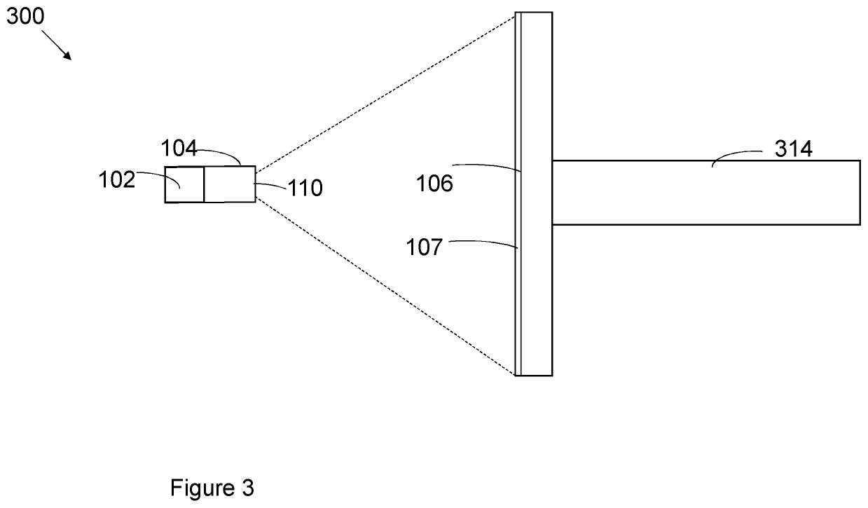

FIG. 3 shows a side-profile schematic view of yet another evaporator pump system 300. The evaporator pump system 300 differs from the evaporator pump system 100 of FIGS. 1 and 200 of FIG. 2 in that: (i) it comprises a cooling element 314 instead of heating elements 112, and (ii) it does not include a collector 108 within the chamber being pumped. The target surface 106 is also shown not to include an array of protrusions, although the presence of such a feature is possible. The cooling element 314 may be the retractable cooling element 214 of FIG. 2.

As the target surface 106 of the evaporator pump system 300 is absent any heating elements, the average and maximum operating temperatures of the target surface during operation of the pump system 300 are lower compared with pump systems 100, 200. As such, the amount of gas released from the target surface is reduced. For example, during operation of the pump system 300, the temperature of the target surface 106 may remain below the melting point of the getter layer. In a specific example, the target surface 106 remains below a temperature of 450K.

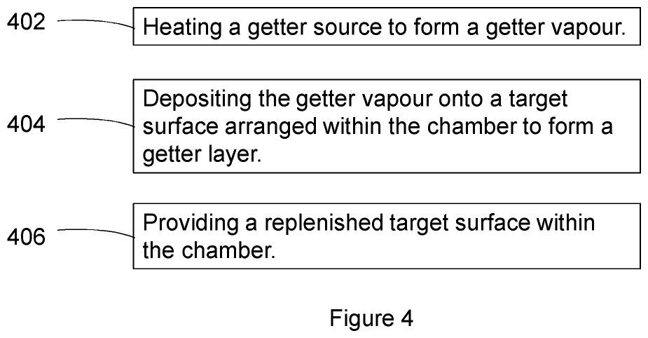

Operation of the evaporator pump systems 100, 200, 300 from FIGS. 1 to 3 will now be described with reference to FIG. 4. The pump systems 100, 200, 300 may be operated in a chamber at partial vacuum, for example, at a pressure less than 10⁻³ mbar (HV) or less than 10⁻⁷ mbar (UHV).

In step 402, the getter source 102 is heated to form a getter vapour.

The getter source 102 comprises solid, or liquid lithium. That is, a lithium-containing alloy or substantially pure lithium. The lithium-containing alloy may comprise greater than 40%, 45%, 50%, 55%, 60%, 65%, 70%, 75%, 80%, 85%, 90%, 95%, or 99% lithium by atomic fraction. An example lithium-containing alloy is 50% lithium-50% tin by atomic fraction.

The primary operating principle of pump systems 100, 200, 300 with a lithium-containing getter layer 107 is chemisorption. Residual gases and vapours, such as hydrogen, oxygen, nitrogen, water, CO, CO₂, hydrocarbons and other species chemically react with lithium (e.g., liquid or solid lithium) and form various chemical compounds. These chemical compounds are the getter products. The getter products are captured by the getter layer 107 through chemical bonding.

As the skilled reader appreciates, alternative lithium alloys, which include constituent elements other than, or in addition to, tin and which do not bind to lithium following its evaporation, are also possible. For example, the lithium alloy may include other alkali metals, such as sodium and/or potassium. The lithium getter source 102 may be loaded into the evaporator 104 under an argon atmosphere to avoid contamination.

If the getter source is substantially pure lithium, the temperature of the evaporator will be above the melting point of the lithium 102 during evaporation. Whereas, if the getter source is a lithium alloy, the temperature of the evaporator will be at least above the solidus temperature, more preferably above the liquidus temperature for that lithium alloy composition. For the sake of conciseness, references herein to “melting point” used in context with a lithium alloy should be interpreted accordingly. For some lithium alloys (e.g., a lithium-tin eutectic alloy), the solidus and liquidus temperatures coincide. Thermo-physical techniques, such as, differential scanning calorimetry (DSC), for determining the liquidus and solidus temperatures of alloys, including lithium, are known to the skilled reader.

Step 402 therefore comprises heating the lithium-containing getter source 102 to a temperature above the melting point of the getter layer in the partial vacuum of the chamber. The heating elements, which provide heating to the getter source 102, may either be remote to (e.g., radio-frequency heating components), or contained within (e.g., filament of wire), the evaporator 104.

The housing of the evaporator 104 may comprise any material which, under the operating conditions of the evaporator pump system 100, 200, 300, does not react with the lithium-containing getter source or its vapour, and which does not break when subject to heating rates in the range of 100K/min. Metallic housings are preferred as they are less prone to fracture upon heating. An example metallic housing is tungsten, tantalum or molybdenum.

In step 404, the getter vapour is deposited onto the target surface 106, which is arranged within the chamber of the evaporation pump system, to form a getter layer 107. The getter layer 107 may be solid, liquid, or a mixture thereof, depending on the temperature of the target surface 106.

For example, the getter layer 107 is a solid where the target surface 106 is (i) below the melting point of lithium with the layer 107 being substantially pure lithium, or (ii) below the solidus temperature for the lithium alloy with the layer 107 being that lithium alloy.

Similarly, the getter layer 107 is a liquid, where the target surface 106 is (i) above the melting point of lithium with the layer 107 being substantially pure lithium, or (ii) above the liquidus temperature for the lithium alloy with the layer 107 being that lithium alloy. The getter layer 107 is partially solid if the layer 107 is a lithium alloy and the target surface 106 is at a temperature between the solidus and liquidus temperatures of that lithium alloy. As detailed above, the getter vapour may be directed toward the target surface 106 by appropriate placement and separation of the evaporator 104 and target surface 106.

Once the getter layer 107 is deposited, it extracts gas from the surrounding partial vacuum, primarily via chemisorption. The getter layer 107 therefore provides a pumping effect.

In general, a partial vacuum includes various different gas species. For example, nitrogen, oxygen or hydrogen containing gases. These gases are known to the skilled reader. Due to the aforementioned mechanism of chemical binding, some gaseous species such as the inert gases (e.g., He, Ar, Ne, Xe) are not expected to be pumped as effectively as other more reactive gases. Therefore, although the evaporation pump system 100, 200, 300 is preferably able to maintain or reduce the total pressure within the chamber in which it is disposed, this is not essential. Systems 100, 200, 300 remain practicable so long as they are able to reduce the partial pressure of at least one gas species inside the chamber.

In step 406, a replenished target surface is provided within the chamber, and onto which further getter vapour can be deposited. The replenished target surface can be provided by: (i) at least partially removing, from the target surface, the getter layer and any chemisorbed, and/or physisorbed products present within the getter layer (step 406a); and/or (ii) arranging a different (second) target surface within the chamber (step 406b). Step 406a and step 406b may be performed concurrently or sequentially.

Step 406a is performed within the chamber and advantageously requires no moving parts. In step 406b, the different (second) target surface may replace the original (first) target surface. Providing a replenished target surface is advantageous because the pump can operate for longer periods of time whilst still remaining efficient. This is because the pumping rate is not as limited by the saturation of the target plate with getter products.

Optionally, in step 408, the first and/or second target surface 106 is cooled to a temperature below that of the melting point of the getter layer in partial vacuum. The cooling can be passive (cooling through radiative heat loss) or active. More specifically, this can be achieved by: (i) reducing, or stopping altogether, the supply of thermal energy from heating elements 112; (ii) arranging cooling elements 214, in thermal contact with the first and/or second target surface; or (iii) a combination thereof.

Cooling encourages condensation of the getter vapour and increases its sticking probability onto the target surface 106. One or more thermocouples may be used to provide feedback to a temperature controller to regulate the temperature of the target surface 106.

In the liquid state, lithium more readily reacts with impinging gas species, possesses higher solubility (solubility increases monotonically with temperature) and higher diffusion rates (diffusion increases monotonically with temperature) for these species. These increases in solubility and diffusion lead to an increase of amount of impurities that can be captured from the partial vacuum.

For these reasons, it may be advantageous to heat the target surface 106 to melt the getter layer 107 during pumping.

In summary, the temperature of the target surface 106 can be used to control:
the phase state of the getter layer (either solid or liquid);
the sticking probability of gases in the partial vacuum onto the surface of the getter layer; and/or
the diffusion rate of chemisorbed and absorbed products into the getter bulk.

Step 406a, of at least partially removing the getter layer 107 and its getter products from the target surface 106, may comprise heating the target surface above the melting point of the getter layer in the partial vacuum. In the pump system 200 shown in FIG. 2, cooling element 214 may be retracted from thermal contact with the target surface prior to, or during step 406a. Step 406a, and the associated subsequent steps, are applicable to the pump systems 100, 200 of FIGS. 1 and 2 only.

The temperature of the first target surface 106 may further be kept below 650K to avoid re-evaporation of the lithium-containing getter layer. Effective removal of the getter layer 107 with its getter products can be achieved if the volume fraction of getter layer is larger than that of the getter products. In that case, the lithium getter layer 107 can melt and flow into the collector 108 and some of the solid or solute impurities (i.e., the getter products) contained within the getter layer 107 will be transferred into the collector 108 with the melted getter layer. Conversely, if the getter layer 107 has been used up to such an extent that the layer on the target surface 106 comprises essentially mostly of getter products, then those products cannot be removed by heating to 650K since those getter products melt at a much higher temperature and the flow of the getter layer 107 is inhibited. In some examples, the getter products form a solid film or crust on the target surface 106 and/or the getter layer. This crust does not melt at 650K and may remain attached to the target surface during melting of the getter layer 107. Other methods (e.g, step 406b) are used to remove the crust from the target surface 106. In step 406a, the target surface may be heated to around 470K to melt the getter layer. The target surface may in other examples be heated to around 470K to 650K, more preferably around 520K to 650K, and even more preferably around 575K, in order to melt the getter layer 107.

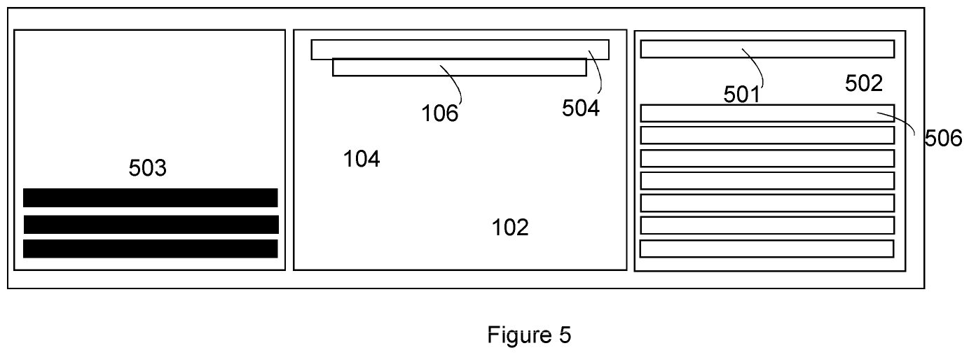

Step 406b may comprise moving the first target surface 106 inside the chamber, and inserting the second target surface in its place within the chamber, using a target surface removal and insertion mechanism (shown in FIG. 5). In an example, the second target surface replaces the position of the first target surface in the chamber so that getter vapour is directed at the second target surface without requiring the evaporator 104 to move. That is, the second target surface is arranged to oppose the opening in the housing so that further getter layers can be deposited on that replenished surface. The first target surface 106 may remain in the chamber during step 406b. Subsequently, the first target surface 106 may, along with other target surfaces, be removed from the chamber. The second target surface may also remain in the chamber for the entirety of step 406b also.

After the first target surface 106 is removed from the chamber, optional step 410b is performed. In step 410b, the removed target surface is “cleaned” (i.e., replenished) to at least partially remove the getter layer and any chemisorbed and/or physisorbed products present within that layer. As the target surface is cleaned outside the chamber, more space is available, and the target surface can be at ambient pressure (e.g., an argon atmosphere at 1 atm). Cleaning the target surface outside the chamber is therefore simpler, and better results are possible compared with inside the chamber.

Example methods of removing the getter layer and its getter products from the target surface 106, outside of the chamber, are: (i) melting; (ii) evaporative distillation or (iii) chemical dissolution.

### Melting

As has already been mentioned, during pumping, the getter layer 107 comprising lithium is used up to form the getter products. If the volume fraction of getter layer 107 is greater than that of the getter products, then it is possible to remove the getter layer 107 along with some of the getter products contained therein by melting the getter layer. With a lithium-containing getter layer 107, this can be achieved by heating the target surface 106 to temperatures above 454K. A collector, similar to those shown in FIGS. 1 and 2, can be used to collect the melted getter layer 107 and the getter products contained therein.

The lithium collected can then be processed by an external lithium loop. A lithium loop is an installation external to the chamber which provides inflow of clean or pure lithium and takes in contaminated or impure lithium. Such a lithium loop may be connected to the collector 108 shown in FIGS. 1 and 2. The circulation of lithium in the loop is maintained by a magnetohydrodynamic pump built into the loop. Lithium loops are known to the skilled reader, and it is sufficient here to say that, in general, lithium loops comprise purification, storage and pumping modules. The lithium collected can preferably, although not necessarily, be delivered to the lithium loop in liquid form without breaking vacuum). Alternatively, the lithium collected can be removed and disposed of in solid form.

### Distillation

In evaporative distillation, the target plate 106 removed from the vacuum chamber is heated to temperatures around, or above 975K. At these high temperatures: (i) the getter products (i.e., the gases chemically bounded to lithium) dissociate from lithium and are released as a gas or vapour from the target plate 106; and (ii) lithium at least partially evaporates. The released gaseous species are pumped out of the distillation chamber, whilst the evaporated lithium condenses on the walls of the distillation chamber. Thereafter, the condensed lithium is collected and cast into, for example, bars so that it can inserted back into pump as a getter source 108. Evaporative distillation therefore substantially removes all of the lithium-containing getter layer and its getter products from the target plate 106. For this reason, a target plate, after having been subject to evaporative distillation, is considered to be “clean” or “replenished”.

In some examples, the lithium and its getter products which are collected in collector 108 can be fed directly into a distillation chamber, or indirectly via a lithium loop. The distillation process described above may then be applied.

### Dissolution

In chemical dissolution, the target plate 106 is immersed in an aqueous solvent (e.g., water) or otherwise subject to that solvent in order to dissolve the getter layer and its products in solution. Other solvents (e.g., a suitable acid) can also be used. The target surface 106, typically a steel, is unaffected by the water or the other solvent. The resulting solution is then disposed with as appropriate. Chemical dissolution therefore substantially removes all of the lithium-containing getter layer and its getter products from the target plate 106. For this reason, a target plate, after having been subject to this process, is considered to be “clean” or “replenished”.

After the getter layer 107 melts in step 406a (or otherwise), it, together with its physisorbed and/or chemisorbed products, flows downwardly on the target surface 106 into the collector 108 due to gravity. The collector 108 in pump systems 100, 200 is therefore arranged beneath the target surface 106 to collect the melted getter layer. The target surface 106 may include a lower-lip or funnel to help direct the melted getter toward the collector 108. In some examples, the target surface 106 is oriented at an angle relative to the direction of gravity, such that it points downwardly and the melted getter can effectively flow into the collector 108. In some examples, the array of protrusions 114 hinders the flow of the melted getter to increase the period of time that the liquid getter acts as a pump. In some examples, the array of protrusions 114 may define channels 202 that funnel the melted getter toward the collector 108.

The collector 108 in pump systems 100, 200 is at a temperature below the melting point of the getter. In an example, it is not heated. In other examples, the collector 108 may be cooled or heated, using equipment known to the skilled reader. The getter 116 therefore solidifies in the collector 108. When required, the solidified getter 116 can be removed by replacing the collector 108. The collected material from the collector 108 can be distilled to separate the lithium from its getter products. The separated lithium can then be reused as a getter source.

In an example, during operation of pump systems 100 or 200, the getter layer 107 solidifies on the target surface 106 and it is heated by the one or more heating elements 112 above the melting point of the getter layer 107 after a predetermined time of pumping. The predetermined time may approximately correspond to the time required to saturate the surface of the getter layer 107. In some examples, the partial vacuum surrounding the evaporation pump system 100 is monitored. After a pressure increase (i.e., due to the rate of gas egress from the vacuum vessel walls exceeding the pumping rate of the getter layer 107), or a pressure plateau (i.e., due to the surface of the getter layer saturating), is detected, the getter layer 107 is melted. In other examples, the temperature of the target surface 106 is maintained above the melting point of the getter (but below the critical temperature, T_{c2}), such that the getter layer 107 remains in the liquid state after condensing.

In other examples, during operation of pump systems 100, 200, 300, the getter layer 107 solidifies on the target surface 106, and heating elements 112 and/or cooling elements 214, 314 are operated to ensure the getter layer remains solid. Successive solid getter layers are then deposited on top of one another on the target surface 106, until the target surface is replenished in step 406.

Regarding step 406a in particular, it is noted that NEGs are not designed for melting. Typically, they are engineering with high porosity (e.g., they are sintered). Melting a NEG would destroy this porosity. Conversely, typical EGs have melting points in excess of 2400K, which are relatively inconvenient to melt. Hence, a lower melting point getter (e.g., with a melting point less than 600K) is desirable. Such a getter would be advantageous because it is more convenient to melt and diffusion rates, even at room temperature, would be measurable (since diffusion scales with homologous temperature).

Substantially pure lithium has a melting point of around 454K and therefore can be readily melted using simple heating equipment in step 406a or otherwise (e.g., using a conventional hot plate). As set out above, an advantage of a liquid getter is that the rate of chemisorption of gaseous species to a liquid getter is greater than to a solid getter.

During step 404 of depositing the lithium-containing getter source 102 onto the target surface 106, the target surface may be held at a temperature below its melting point, for example, at around 300 to 400K.

The numerical order of these method steps is not intended to be limiting. For example, step 408 can be performed before, after, or even concurrently with, step 406a. Step 406a can be performed before, after or concurrently with step 406b. The skilled reader will appreciate there are other ordered combinations for these method steps, which lead to working examples.

The components of the evaporation pump systems 100, 200, 300 are easy and cheap to make: the evaporator 104 and collector 108 are containers that are readily machinable; and, the target surface 106 could be a disc. The array of protrusions 114 in FIG. 1 could be formed from pins fixed (e.g., welded) onto the rim of a cylinder. In an example, the disc and cylinder are stainless steel. In a specific example, the disc is around 30 cm in diameter and the cylinder has a length of 5 cm. In a specific example, the protrusions 114 extend around 10 mm from the target surface 106 with each protrusion 114 having a radius of around 1 mm, and the protrusions 114 are regularly spaced by around 5 mm.

An alternative way to increase the surface area of the getter layer 107 (whilst maintaining the same projected area) is to shape the target surface 106 so that it is not flat. For example, the surface of the target surface 106 (which can still be formed from a disc) may have a saw-tooth surface profile or a waved profile. Other surface profiles, which increase the surface area of the target surface 106, are possible. In a specific example, the surface profiles have a regular pattern. The skilled reader knows the methods for developing these surface profiles as well as others onto solid surfaces.

FIG. 5 is a schematic illustration of a target surface insertion and removal mechanism 500 for use with an evaporator pump system installed in a chamber. The target surface insertion and removal mechanism is for providing a replenished (or “clean”) target plate 506 in place of target plate 106 that was previously in a position to receive the deposited getter layer 107, i.e., a “dirty” plate. The mechanism comprises: a translation device 501 for moving a clean target plate 506 and removing the target plate 106. The translation device 501 may be actuated from the atmospheric pressure side in order to provide the necessary motive force to replace target plate 106 with clean target plate 506. The mechanism further comprises dedicated storage modules 502, 503 for respectively storing the “clean” and “used” target surfaces. In some examples, these storage modules 502, 503 are located within the chamber being pumped. In such examples, the translation device 501 can advantageously be actuated to replace plates 106, 506 without having to depressurise the chamber in which the pump system is disposed. Alternatively, the storage modules 502, 503 can be located outside the chamber, although that set-up requires depressurising the system each time the plates need changing.

A locking mechanism 504 can be used to retain the target surface 106 in the appropriate position for receiving the getter vapour from evaporator 104, and in contact with any heating 112 or cooling elements 214, 314 present in the pump system 100, 200, 300. The locking mechanism 504 is operable to “unlock” so that the plate 106 in the chamber can be replaced with clean plate 506.

In general, the target surface insertion and removal mechanism is activated conditional upon a predetermined condition being met. The predetermined condition may be a particular getter saturation, the thickness of the layer on the target plate i.e. the getter layer and its products, or after a predefined time has elapsed. In general, the target surface 106 is considered to be “saturated” with getter products when the predetermined condition is met. Activation of the target surface insertion and removal mechanism 500 comprises steps of: (i) releasing the locking mechanism 504; (ii) moving the target plate 106 with getter layer 107 to storage module 503; (iii) moving the clean target plate 506 from storage module 502 into a position to receive the getter vapour from evaporator 104; (iv) engaging the locking mechanism 504 to retain the new target plate 506 in place. These steps can be repeated until either a) there are no new target plates 506 in the storage module 502 or b) the storage module 503 is full. When one of these two conditions is fulfilled, a reloading procedure is performed.

The reloading procedure comprises either extracting target plates 106 from storage module 503 for processing/cleaning, or loading of “clean” target plates 506 into storage module 502. The reloading procedure can be performed under partial vacuum using a load-lock device, or, at atmospheric pressure by filling the chamber with an inert gas such as argon or helium. The use of inert gases is preferred since that avoids contaminating the lithium. An argon-filled (or other inert gas filled) glove box can then be connected or fitted to a port of the pump chamber and in which the “clean” target plates 506 can be placed for insertion into storage module 502. The glove box can be a temporary or permanent installation. The port is then opened and an operator (either a human or a robotic device) can extract the saturated plates 106 from storage module 503 and/or load clean target plates 106 into storage module 502. The port is then closed. If reloading is performed at elevated pressures (e.g., atmospheric pressure), pumping is stopped, and the pump system 100, 200, 300 is disconnected from the chamber it is attached to. After reloading is complete: (i) partial vacuum is restored in the chamber by means of other vacuum pumps, as explained below; (ii) pump system 100, 200, 300 is connected back to the chamber it is attached to; and (iii) operation of pump system 100, 200, 300 can be resumed.

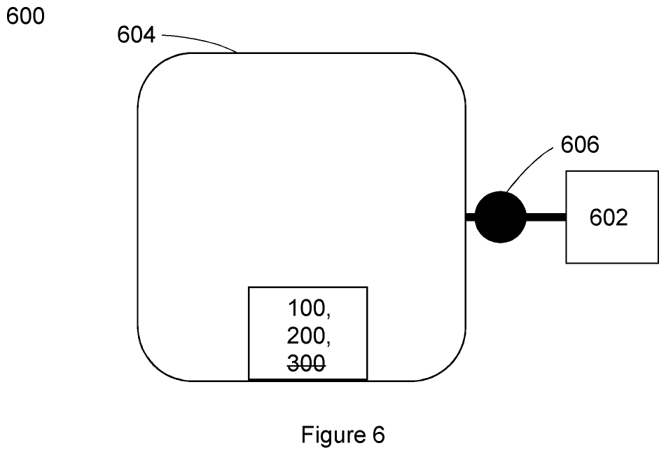

Referring now to FIG. 6, a schematic illustration of a pump assembly 600 for a vessel or chamber 604 is shown. The pump assembly 600 includes: the evaporation pump system 100, 200, 300 of any of FIG. 1, 2 or 3 (as described in detail above) disposed within the vessel 604; and one or more vacuum pumps 602, fluidly connected to vessel via a valve 706. In an example, the one or more vacuum pumps 602 comprise a turbo-molecular pump and a fore-vacuum pump. The one or more vacuum pumps 602 are operable to reduce the pressure in the vessel to that of partial vacuum (e.g., to HV). Types of vacuum pump(s) 602 are known to the skilled reader. Optionally, the pump assembly 600 includes the target surface insertion and replacement mechanism 500 of FIG. 5 (not shown), and in particular, although not exclusively, where the pump system in the assembly is that shown in FIG. 3. Optionally, one or more booster pumps, fluidly connected in series with the one or more fore-vacuum pumps 602, may also be used (not shown).

In some examples, the vessel 604 may be a magnetic confinement plasma chamber, for example, a tokamak, preferably a spherical tokamak. Preferably, but not necessarily, the aspect ratio of the spherical tokamak is less than or equal to 2.5. The aspect ratio is the ratio of the major and minor radii of the toroidal plasma-confining regions of the tokamak. The evaporation pump systems 100, 200, 300 may also be provided within a stellarator, or other plasma confinement vessel. In specific examples, the evaporation pump systems 100, 200, 300 may be installed in the divertor of the plasma vessel (e.g., tokamak vacuum vessel), close to, along or around the mid-plane of the plasma chamber (e.g., tokamak vacuum vessel) or within ports inside the plasma vessel (e.g., tokamak vacuum vessel).

An evaporation pump system 100, 200, 300 comprising a lithium-containing getter source 102 is particularly well suited for use in a magnetic confinement plasma chamber (e.g., a tokamak) because:
lithium is a “low Z” element, meaning that operation of the evaporation pump system 100, 200, 300 does not adversely affect plasma operation (e.g., stability);
the evaporation pump system 100, 200, 300 is compact, meaning it can be installed in spherical tokamaks (where space is at a premium);
the pumping efficiency of the evaporation pump system 100, 200, 300 is not adversely degraded by being in contact with the plasma or increase in temperature; and
lithium chemically binds hydrogen and its isotopes (i.e., deuterium and tritium), which are the dominant species in a tokamak. These captured hydrogen isotopes can be safely extracted from the getter layer elsewhere.

It should be noted that the “getter source” 102 and “getter layer” 107 may comprise the same or different material. For example, the getter source 102 and getter layer 107 could both be pure lithium, or both be a lithium-containing alloy of substantially equivalent composition. In a further example, the getter source 102 could be a lithium-containing alloy (e.g., as low as 40 at % lithium), whereas the getter layer, which is a product of the evaporation and condensation of the getter source 102, is substantially pure lithium. In a further example, the getter source could be a lithium-containing alloy of a particular composition and the getter layer is a lithium-containing alloy of a different composition. The skilled reader will appreciate that, with a lithium-containing alloy as the getter source, the composition of the getter layer that deposits on the target surface 106 can be determined from the appropriate phase diagram for a particular pressure and temperature.

References to melting point, liquidus temperature, solidus temperature, and boiling point throughout the specification should be interpreted as phase transition temperatures at the pressure of the partial vacuum, unless expressed to the contrary.

Although the invention has been described in terms of preferred embodiments as set forth above, it should be understood that these embodiments are illustrative only and that the claims are not limited to those embodiments. Features from different examples may be combined as appropriate to form other working examples. The invention includes aspects defined by the following numbered paragraphs, which correspond with the claims of the priority application:

Paragraph 1: A method of operating an evaporation pump system in a partial vacuum, the method comprising: heating a getter source to form a getter vapour; depositing the getter vapour onto a target surface to form a getter layer by controlling the temperature of the target surface; and heating the target surface above the melting point of the getter layer in the partial vacuum.

Paragraph 2: The method according to paragraph 1, wherein the getter source comprises substantially pure lithium, or, a lithium-containing alloy, said alloy comprising greater than 90%, preferably greater than 95%, more preferably greater than 99% lithium by atomic fraction.

Paragraph 3: The method according to any one of paragraphs 1 and 2, wherein: during said depositing step, the temperature of the target surface is lower than 454K, and during said heating step, the temperature of the target surface is around 470 to 670K.

Paragraph 4: The method according to paragraph 2, wherein the temperature of the target surface remains below around 1100K during said depositing and heating steps.

Paragraph 5: The method according to any one of paragraphs 1 to 4, wherein the temperature of the target surface remains below the melting point of the getter vapour in the partial vacuum until said step of heating the target surface above its melting point.

Paragraph 6: The method according to any one of paragraphs 1 to 5, wherein said step of heating the target surface is performed a predetermined time after the getter layer is deposited onto the target surface, or, after it is detected that the pressure of the partial vacuum has increased or plateaued.

Paragraph 7: The method according to any preceding paragraph, wherein the melted getter layer, formed by said step of heating the target surface, flows downwardly on the target surface via gravity and the method further comprises: collecting the melted getter layer in a collector.

Paragraph 8: The method according to paragraph 7, which further comprises solidifying said melted getter in said collector, after said collecting step.

Paragraph 9: The method according to any preceding paragraph, wherein the getter source is heated to a temperature, which is above the melting point of the getter source in the partial vacuum and below a first critical temperature.

Paragraph 10: The method according to paragraph 9, when dependent on paragraph 2, wherein the getter source is contained within a housing comprised from boron-nitride and the first critical temperature is 1100K.

Paragraph 11: The method according to any preceding paragraph, wherein the partial vacuum has a pressure of less than 10⁻³ mbar, more preferably less than 10⁻⁷ mbar.

Paragraph 12: The method according to any preceding paragraph, wherein said step of heating a getter source comprises passing an electrical current through a filament of wire in contact with, or close to, the getter source.

Paragraph 13: An evaporation pump system comprising: a housing configured to contain a getter source, wherein the housing comprises an opening at one end; a first heater for heating said getter source; a target surface arranged opposing said opening; a second heater for heating said target surface, said evaporation pump system being arranged so that, in use: the getter source is heated by said first heater in the housing to form getter vapour; the getter vapour is deposited onto the target surface to form a getter layer; and the target surface is heated by said second heater to a temperature above the melting point of the getter layer.

Paragraph 14: The evaporation pump system according to paragraph 13, further comprising a collector arranged relative to the target surface to collect the melted getter layer, formed by heating the target surface above the melting point of the getter layer.

Paragraph 15: The evaporation pump system according to any one of paragraphs 13 to 14, wherein the getter source is substantially pure lithium, or, a lithium-containing alloy, said alloy comprising greater than 90%, preferably greater than 95%, more preferably greater than 99% lithium by atomic

Paragraph 16: The evaporation pump system according to any one of paragraphs 13 to 15, wherein the target surface comprises an array of protrusions, each protrusion in said array either extending away from, or into, the target surface.

Paragraph 17: The evaporation pump system according to paragraph 16, wherein said array is cubic, hexagonal or orthorhombic.

Paragraph 18: The evaporation pump system according to paragraph 16, wherein said array is irregular and defines a plurality of channels that are configured to direct the flow of the melted getter layer, formed by heating the target surface above the melting point of the getter layer, towards the collector.

Paragraph 19: The evaporation pump system according to any one of paragraphs 13 to 18, wherein said second heater comprises one or more heating elements attached to, or forming an integral part of, the target surface.

Paragraph 20: The evaporation pump system according to any one of paragraphs 13 to 18, wherein said first heater comprises one or more heating elements in contact with, or close to, the getter source or its housing.

Paragraph 21: The evaporation pump system according to any of paragraph 13 to 20, wherein the target surface is a plate or disc.

Paragraph 22: The evaporation pump system according to paragraph 20, wherein the target plate has a diameter of around 30 cm; the spacing in the array of protrusions is around 5 mm, each protrusion in the array has a radius of around 1 mm, and each protrusion in the array extends 10 mm from the target surface.

Paragraph 23: A pump assembly for a vessel, comprising: an evaporation pump system according to any one of paragraph 13 to 22; and one or pumps fluidly connected to the vessel and operable to reduce the pressure within the vessel to partial vacuum.

Paragraph 24: The pump assembly according to paragraph 23, wherein the vessel is a

Paragraph 25: The pump assembly according to any one of paragraphs 23 to 24, wherein the evaporation pump system is located in the divertor of the tokamak; close to the mid-plane of the tokamak; or within ports inside the tokamak vessel.

1. A method of operating an evaporation pump system in a chamber at partial vacuum, the method comprising:
heating a getter source, comprising lithium, to form a getter vapour;
depositing the getter vapour onto a first target surface arranged within the chamber to form a getter layer; and
providing a replenished target surface within the chamber, and onto which the getter vapour can be deposited, by
arranging a second target surface within the chamber.

2. (canceled)

3. (canceled)

4. The method according to claim 1, wherein the getter source is substantially pure lithium, or, a lithium-containing alloy comprising greater than 90%, preferably greater than 95%, more preferably greater than 99% lithium by atomic fraction.

5. The method according to claim 1, wherein the getter source is a lithium-containing alloy comprising greater than 40%, preferably greater than 45%, more preferably greater than 50%, even more preferably greater than 55% lithium by atomic fraction.

6. The method according to claim 1, wherein during said depositing step, the method comprises:
cooling the first target surface to a temperature below that of the melting point of the getter layer in the partial vacuum by arranging one or more cooling elements in thermal contact with the first target surface.

7. (canceled)

8. The method according to claim 17, wherein the evaporation pump system comprises one or more retractable cooling elements, and the method further comprises:
retracting the or each retractable cooling element from thermal contact with the first target surface.

9. (canceled)

10. (canceled)

11. The method according to claim 1, wherein, arranging the second target surface within the chamber comprises:
arranging the second target surface in place of the first target surface.

12. The method according to claim 1, further comprising:
removing the first target surface from the chamber; and
replenishing the first target surface by at least partially removing, from the first target surface, the getter layer and any chemisorbed and/or physisorbed products present within the getter layer.

13. The method according to claim 12, wherein the getter layer and said products are removed from the first target surface by:
heating the first target surface to a temperature around 975K until substantially all compounds from getter layer are evaporated.

14. The method according to claim 12, wherein the getter layer and said products are removed from the first target surface by dissolution.

15. An evaporation pump system comprising:
a housing configured to contain a getter source, wherein the housing comprises an opening at one end;
a first heater for heating said getter source;
a first target surface arranged opposing said opening;
a target surface replenishment mechanism configured to provide a replenished target surface onto which getter vapour can be deposited, by:
arranging a second target surface to oppose said opening of the housing, said evaporation pump system being arranged so that, in use:
the getter source is heated by said first heater in the housing to form getter vapour;
the getter vapour is deposited onto the first and/or second target surface to form a getter layer,
wherein the getter source comprises lithium.

16. The evaporation pump system according to claim 15, wherein the getter source is substantially pure lithium, or, a lithium-containing alloy comprising greater than 90%, preferably greater than 95%, more preferably greater than 99% lithium by atomic fraction.

17. The evaporation pump system according to claim 15, wherein the getter source is a lithium-containing alloy comprising greater than 40%, preferably greater than 45%, more preferably greater than 50%, even more preferably greater than 55% lithium by atomic fraction.

18. (canceled)

19. (canceled)

20. The evaporation pump system according to claim 15, further comprising one or more cooling elements operable to be arranged in thermal contact with the first and/or second target surface.

21. The evaporation pump system according to claim 15, wherein the target surface replenishment mechanism comprises a target surface replacement mechanism for arranging the second target surface in place of the first target surface.

22. A pump assembly for a vessel, comprising:
an evaporation pump system according to claim 15; and
one or more vacuum pumps fluidly connected to the vessel and operable to reduce the pressure within the vessel to partial vacuum.

23. The pump assembly according to claim 22, wherein the vessel is a tokamak, preferably a spherical tokamak, and more preferably a spherical tokamak having an aspect ratio of less than or equal to 2.5, the aspect ratio being defined as the ratio of the major and minor radii of a toroidal plasma-confining region of the tokamak.

24. The pump assembly according to claim 23, wherein the evaporation pump system is located in the divertor of the tokamak;
close to the mid-plane of the tokamak; or within ports inside the tokamak vessel.
